(19) United States
(12) Patent Application Publication
(10) Pub. No.: US 2026/0235451 A1
(43) Pub. Date: Aug. 13, 2026

(54) TEMPERATURE SENSORS AND APPLICATIONS IN WIRELESS CHARGING

(71) Applicant: Tesla, Inc., Austin, TX (US)

(72) Inventors: Xuan Zhang, Sunnyvale, CA (US); Suzanne O'Meara, San Francisco, CA (US); Xiaotian Fan, San Bruno, CA (US)

(21) Appl. No.: 19/157,590

(22) PCT Filed: Feb. 27, 2024
(86) PCT No.: PCT/US2024/017498

§ 371 Date: Aug. 18, 2025

Related U.S. Application Data
(60) Provisional application No. 63/487,554, filed on Feb. 28, 2023.

(51) Int. Cl. G01K 7/02; B60L 53/124; G01K 1/02; H02J 50/10; H05K 1/02; H05K 1/185

(52) U.S. Cl. CPC G01K 7/02; B60L 53/124; G01K 1/026; H02J 50/10; H05K 1/0298; H05K 1/185; H05K 2201/10151; H05K 2201/10219

(57) ABSTRACT

Some embodiments of the present disclosure relate to systems and methods that utilize bimetallic thermocouples embedded in a printed circuit board (PCB) for sensing temperature. In some embodiments, a PCB includes a thermocouple embedded in the PCB. The thermocouple comprises a first metallic trace and a second metallic trace. The thermocouple is configured to generate a voltage indicative of temperature associated with the PCB. In some embodiments, thermocouples or thermistors are utilized by a wireless charging pad to sense temperature.

### CROSS-REFERENCE TO PRIORITY APPLICATION

This application claims priority to U.S. Provisional Patent Application No. 63/487,554, entitled “TEMPERATURE SENSING IN WIRELESS CHARGING,” filed on Feb. 28, 2023, the technical disclosure of which is hereby incorporated by reference in its entirety and for all purposes.

### TECHNICAL FIELD

The present disclosure relates to systems and methods for temperature sensing. More particularly, embodiments of the present disclosure relate to temperature sensors, and circuits or components for sensing temperature.

### BACKGROUND

A wide variety of temperature sensors can be utilized by a device or a system to detect one or more temperatures associated with the device or the system. For example, a bimetallic thermocouple that generates a voltage signal between two ends of two metallic traces is used in various devices to detect temperature. Temperature sensing can be implemented in a variety of applications.

### SUMMARY OF CERTAIN INVENTIVE ASPECTS

The systems, methods and devices of this disclosure each have several innovative embodiments, no single one of which is solely responsible for all of the desirable attributes disclosed herein. Details of one or more implementations of the subject matter described in this specification are set forth in the accompanying drawings and the description below.

In some aspects, the techniques described herein relate to a printed circuit board (PCB), including: a thermocouple embedded in the PCB, the thermocouple including a first metallic trace and a second metallic trace, wherein the thermocouple is configured to generate a voltage indicative of temperature.

In some aspects, the techniques described herein relate to a PCB, wherein the first metallic trace includes copper, and wherein the second metallic trace includes constantan.

In some aspects, the techniques described herein relate to a PCB, further including a dielectric layer positioned between the first metallic trace and the second metallic trace.

In some aspects, the techniques described herein relate to a PCB, further including a second dielectric layer and a third dielectric layer, wherein the first metallic trace and the second metallic trace are positioned between the second dielectric layer and the third dielectric layer.

In some aspects, the techniques described herein relate to a PCB, further including a second thermocouple embedded in the PCB, the second thermocouple configured to generate a second voltage indicative of second temperature, wherein the temperature and the second temperature are associated with different locations.

In some aspects, the techniques described herein relate to a PCB, wherein a first metallic trace of the second thermocouple has an end shorted to the first metallic trace of the thermocouple, and wherein a second metallic trace of the second thermocouple has an end shorted to the second metallic trace of the thermocouple.

In some aspects, the techniques described herein relate to a PCB, wherein the thermocouple and the second thermocouple are arranged in parallel.

In some aspects, the techniques described herein relate to a PCB, wherein the thermocouple and the second thermocouple are connected to a same hot junction.

In some aspects, the techniques described herein relate to a PCB, further including: a surface layer positioned over the thermocouple, wherein the surface layer includes a coil configured to generate an electromagnetic field for wireless charging.

In some aspects, the techniques described herein relate to a PCB, further including 100 additional embedded thermocouples.

In some aspects, the techniques described herein relate to a wireless charging pad including the PCB.

In some aspects, the techniques described herein relate to a PCB assembly including the PCB and a processing circuit, the processing circuit configured to determine the temperature based on the voltage.

In some aspects, the techniques described herein relate to a charging pad including: a coil configured to generate an electromagnetic field for wireless charging; one or more sensors configured to generate one or more sensing signals for thermally detecting an object positioned over the coil; and a processing circuit in communication with the one or more sensors, the processing circuit configured to control operation of the charging pad based at least on the one or more sensing signals.

In some aspects, the techniques described herein relate to a charging pad, wherein the charging pad is configured to thermally detect the object while the coil wirelessly transfers power to a second coil in a vehicle pad of a vehicle.

In some aspects, the techniques described herein relate to a charging pad, wherein the one or more sensors include thermocouples embedded in a printed circuit board.

In some aspects, the techniques described herein relate to a charging pad, wherein the thermocouples are T type thermocouples.

In some aspects, the techniques described herein relate to a charging pad, wherein the one or more sensors include surface-mounted thermocouples.

In some aspects, the techniques described herein relate to a charging pad, wherein the one or more sensors include one hundred thermistors.

In some aspects, the techniques described herein relate to a charging pad, wherein the processing circuit is configured to control operation of the charging pad based at least on the one or more sensing signals by at least: determining, based on the one or more sensing signals, that the object is positioned over the coil; and responsive to determining that the object is positioned over the coil, causing the coil to cease generating the electromagnetic field.

In some aspects, the techniques described herein relate to a charging pad, wherein a maximum dimension of the object is less than 50 millimeters.

In some aspects, the techniques described herein relate to a charging pad, wherein the charging pad is configured to connect to an external power source and is dimensioned to be positioned under a vehicle.

In some aspects, the techniques described herein relate to a method of wireless charging with thermal object detection, the method including: while wirelessly transferring power between a wireless charging pad and a vehicle pad of a vehicle, thermally detecting on object positioned between the wireless charging pad and the vehicle pad; and in response to the thermally detecting, ceasing the wirelessly transferring power.

In some aspects, the techniques described herein relate to a method, wherein the object is positioned on a surface of the wireless charging pad.

In some aspects, the techniques described herein relate to a method, wherein the object has a maximum dimension of 50 millimeters or less.

In some aspects, the techniques described herein relate to a method, wherein the object includes metal.

In some aspects, the techniques described herein relate to a method, wherein the thermally detecting is performed using a thermocouple embedded in a printed circuit board.

### BRIEF DESCRIPTION OF THE DRAWINGS

Throughout the drawings, reference numbers are re-used to indicate correspondence between referenced elements. The drawings are provided to illustrate examples of the subject matter described herein and not to limit the scope thereof.

Embodiments of the present disclosure are described with reference to the accompanying drawings, in which like reference characters reference like elements, and wherein:

FIG. 1 illustrates an example bimetallic thermocouple.

FIG. 2 shows an example printed circuit board (PCB) with embedded bimetallic thermocouples in accordance with some embodiments of the present disclosure.

FIG. 3A illustrates example connections between bimetallic thermocouples in accordance with embodiments of the present disclosure.

FIG. 3B illustrates an example pattern of bimetallic thermocouples in accordance with various aspects of the present disclosure.

FIG. 4A is a diagram of a wireless charging system including a wireless charger in which temperature sensors can be deployed in accordance with various aspects of the present disclosure.

FIG. 4B illustrates an example of a wireless charger and a vehicle in accordance with embodiments of the present disclosure.

FIG. 4C illustrates a top view of an example of a wireless charger and a vehicle in accordance with embodiments of the present disclosure.

FIG. 4D is a block diagram which illustrates an example of a wireless charger and a vehicle in accordance with embodiments of the present disclosure.

FIG. 5A is a schematic which illustrates an example wireless charger in accordance with embodiments of the present disclosure.

FIG. 5B illustrates example components integrated within the wireless charger of FIG. 5A in accordance with embodiments of the present disclosure.

FIG. 5C illustrates example temperature sensors integrated within the wireless charger of FIG. 5A in accordance with some embodiments of the present disclosure.

FIG. 5D illustrates an example representation of an object above the wireless charger of FIG. 5A that can be detected in accordance with embodiments of the present disclosure.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. The headings are provided for convenience only and do not impact the scope or meaning of the claims.

Generally described, one or more aspects of the present disclosure relate to systems and methods that utilize one or more bimetallic thermocouples embedded in a printed circuit board (PCB) for sensing temperature. More specifically, some embodiments of the present disclosure relate to one or more bimetallic thermocouples, where each bimetallic thermocouple includes two metallic traces that are in one or more metal layers of a PCB. Instead of deploying the one or more bimetallic thermocouples on a surface of the PCB, embedding bimetallic thermocouple(s) into metal layer(s) of the PCB can advantageously conserve area on the surface (e.g., top surface) of the PCB, increase integration of bimetallic thermocouples and associated metallic traces with the PCB, reduce cost of manufacturing and complexity of assembly, or any suitable combination thereof.

In some embodiments, a bimetallic thermocouple embedded in a PCB (e.g., in one or more metal layers of the PCB) may be made of certain combinations of metals. This can balance a tradeoff between temperature sensing performance of the bimetallic thermocouple and cost of manufacturing the PCB. For example, the bimetallic thermocouple embedded in the PCB may include one metallic trace made of copper and the other metallic trace made of constantan.

In some embodiments, a plurality of bimetallic thermocouples and/or other suitable thermal sensors may be utilized by a wireless charging pad to sense one or more temperatures (e.g., temperature at a particular location of the wireless charging pad or an average temperature over a larger or entire area of the wireless charging pad) associated with the wireless charging pad. To reduce signal processing complexity and number of temperature measurements, in some embodiments, some traces between the plurality of bimetallic thermocouples may be shorted such that an average temperature associated with various locations of a PCB may be determined in one sensing signal measurement. In some embodiments, bimetallic thermocouples (e.g., embedded in a PCB or mounted on a surface of the PCB) or/or other suitable types of thermal sensors (e.g., thermistors) may be utilized by a wireless charging pad to thermally detect foreign objects (e.g., a metallic object) between the wireless charging pad and another wireless charging pad.

A wide variety of temperature sensors can be utilized by a device or a system to detect one or more temperatures associated with the device or the system. For example, a bimetallic thermocouple that generates a voltage signal between two ends of two metallic traces is used in various devices to detect temperature. Typically, metallic traces of bimetallic thermocouples are routed on or above the top of boards (e.g., a coil board, a PCB, or the like) for sensing temperatures. Routing metallic traces of bimetallic thermocouples on top of a board may occupy a surface area of the board that otherwise can be used for other purposes (e.g., for mounting and/or connecting other circuitry of the system). Additionally, design complexity and cost associated with manufacturing the board may increase because of a constrained top surface area of the board with thermocouple traces on the PCB surface. As such, it may be desirable to embed bimetallic thermocouples into one or more layers of the board.

Embedding or integrating bimetallic thermocouples into the one or more layers of a board can be challenging. For example, it may not be feasible to route certain types of metals in layers of a PCB while meeting technical specifications for both sensing performance of thermocouples and cost of manufacturing the PCB. More specifically, some thermocouple types may provide desirable temperature sensing performance (e.g., sensitivity, accuracy, or the like) but may be too costly to be embedded into metal layers of a PCB, while other thermocouple types may be more economically embedded into metal layers of the PCB but exhibit inferior temperature sensing performance.

To address at least a portion of the above identified technical problems, some aspects of the disclosed technology relate to a PCB with one or more embedded bimetallic thermocouples in one or more metal layers of the PCB for sensing the temperatures associated with the PCB. To achieve accurate temperature sensing based on bimetallic thermocouples while maintaining manufacturing parameters for the PCB, the one or more bimetallic thermocouples may be Type T thermocouples. More specifically, the one or more bimetallic thermocouples embedded in the PCB may utilize copper as one metallic trace and constantan as the other metallic trace.

In some embodiments, a PCB may include a first bimetallic thermocouple that is in one or more metal layers of the PCB. The first bimetallic thermocouple may include a copper trace and a constantan trace. The first bimetallic thermocouple may be configured to sense a temperature at a location (e.g., top right corner) and/or in an area of the PCB. For example, one end of the copper trace of the first bimetallic thermocouple may be shorted with one end of the constantan trace of the first bimetallic thermocouple. A voltage difference between the other end of the copper trace of the first bimetallic thermocouple and the other end of the constantan trace of the first bimetallic thermocouple may be measured by a processing circuit to determine the temperature at the location of the PCB.

In some embodiments, the PCB may include a second bimetallic thermocouple that is in one or more metal layers of the PCB. The second bimetallic thermocouple may include a copper trace and a constantan trace, where one end of the copper trace is shorted with one end of the constantan trace. The second bimetallic thermocouple may be configured to sense a temperature at another location (e.g., bottom left corner) of the PCB.

In some embodiments, to reduce signal processing complexity and number of temperature measurements, the copper trace of the first bimetallic thermocouple and the copper trace of the second bimetallic thermocouple may be shorted, and the constantan trace of the first bimetallic thermocouple and the constantan trace of the second bimetallic thermocouple may be shorted. Thus, an average temperature of the temperature sensed by the first bimetallic thermocouple and the temperature sensed by the second bimetallic thermocouple may be determined.

More specifically, the copper trace of the first bimetallic thermocouple and the copper trace of the second bimetallic thermocouple may be connected to an input terminal of a processing circuit, and the constantan trace of the first bimetallic thermocouple and the constantan trace of the second bimetallic thermocouple may be connected to another input terminal of the processing circuit. As such, a voltage difference measured by a processing circuit may be a weighted average (based on relative resistances between the first bimetallic thermocouple and the second bimetallic thermocouple) of voltage differences between copper traces and constantan traces of the first bimetallic thermocouple and the second bimetallic thermocouple. Thus, the processing circuit may measure an average temperature associated with the first bimetallic thermocouple and the second bimetallic thermocouple in one electrical signal measurement.

Thermal based object detection can be desirable in wireless charging applications, such as in wireless charging applications associated with charging a battery pack of a vehicle. A heated object on a surface of a wireless charging pad can be detected by thermal object detection. This can detect a metal object positioned on the wireless charging pad that heats up during wireless charging, for example. The wireless charging can be stopped in response to detecting the metal object. This can prevent ignition of a metal object with good contact to a surface of a wireless charging pad during wireless charging.

In some embodiments, bimetallic thermocouples embedded in a PCB may be utilized by a wireless charging pad to thermally detect foreign object(s) between the wireless charging pad and another wireless charging pad. Besides using the bimetallic thermocouples embedded in the PCB, other types of bimetallic thermocouples (e.g., surface mounted bimetallic thermocouples) and/or thermal sensors (e.g., thermistors) may be utilized by the wireless charging pad to thermally detect a foreign object.

For example, in some embodiments, the wireless charging pad may include a first coil, one or more temperature sensors (e.g., bimetallic thermocouples embedded in PCB, surface mounted bimetallic thermocouples, thermistors), and a processing circuit or processor in communication with the one or more temperature sensors. The wireless charging pad may be used for wireless power transfer between the first coil and a second coil. The first coil may be configured to generate an electromagnetic field for wireless charging. The one or more temperature sensors may be configured to generate one or more sensing signals for thermally detecting an object positioned between the first coil and the second coil. The processing circuit may be configured to control operation of the first coil based at least on the one or more sensing signals. For example, thermal object detection can detect a metallic object. Upon detection of the metallic object, the processing circuit can cause the wireless charging pad to cease wirelessly transferring power, for example. This can prevent the metallic object from overheating and/or igniting.

Although aspects of the present disclosure will be described with regard to illustrative components, interactions, and routines, one skilled in the relevant art will appreciate that one or more aspects of the present disclosure may be implemented in accordance with various environments, system architectures, customer computing device architectures, and the like. Similarly, references to specific devices, such as a wireless charging pad, can be considered to be general references and not intended to provide additional meaning or configurations for the individual wireless charging pad. Still, further, illustrations and exemplary configurations are not intended to be limited and should not be construed as limiting the scope of the present disclosure. Additionally, the examples are intended to be illustrative in nature and should not be construed as limiting.

### Overview of Bimetallic Thermocouples

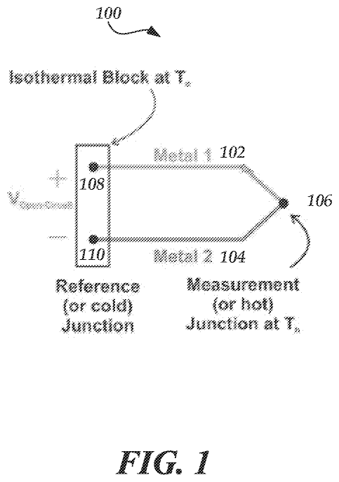

FIG. 1 shows an example bimetallic thermocouple 100. The bimetallic thermocouple 100 includes a first metallic trace 102 and a second metallic trace 104. The first metallic trace 102 and the second metallic trace 104 are made of different types of metals and/or alloys (e.g., iron, chromel, alumel, platinum, rhodium, copper, constantan, or the like) having different Seebeck coefficients. The types of metals for making the first metallic trace 102 and the second metallic trace 104 may be selected based on desired temperature sensing ranges (e.g., chromel and alumel can be selected for sensing a temperature range between 270° C. to 1370° C.) and/or applications.

As shown in FIG. 1, one end of the first metallic trace 102 and one end of the second metallic trace 104 are shorted together to form a junction 106 (e.g., a “hot” junction). The other end 108 of the first metallic trace 102 and the other end 110 of second the metallic trace 104 are not electrically connected and may be kept approximately at the same temperature, and may be viewed as a “cold” junction. Because of different temperature sensing characteristics, a voltage difference can be measured at the “cold” junction (e.g., between the other end 108 of the first metallic trace 102 and the other end 110 of the second metallic trace 104) when a temperature difference appears between the “hot” junction and the “cold” junction. By measuring and processing the voltage difference, a temperature associated with the bimetallic thermocouple 100 (e.g., temperature at the junction 106) can be determined. The thermocouple output voltage across ends 108 and 110 of the metallic traces can act as a function of hot junction temperature. Based on an equation relating hot junction temperature to thermocouple output voltage for the particular materials of metallic traces of a thermocouple, the hot junction temperature can be determined for a measured thermocouple output voltage.

### PCB Embedded Bimetallic Thermocouples

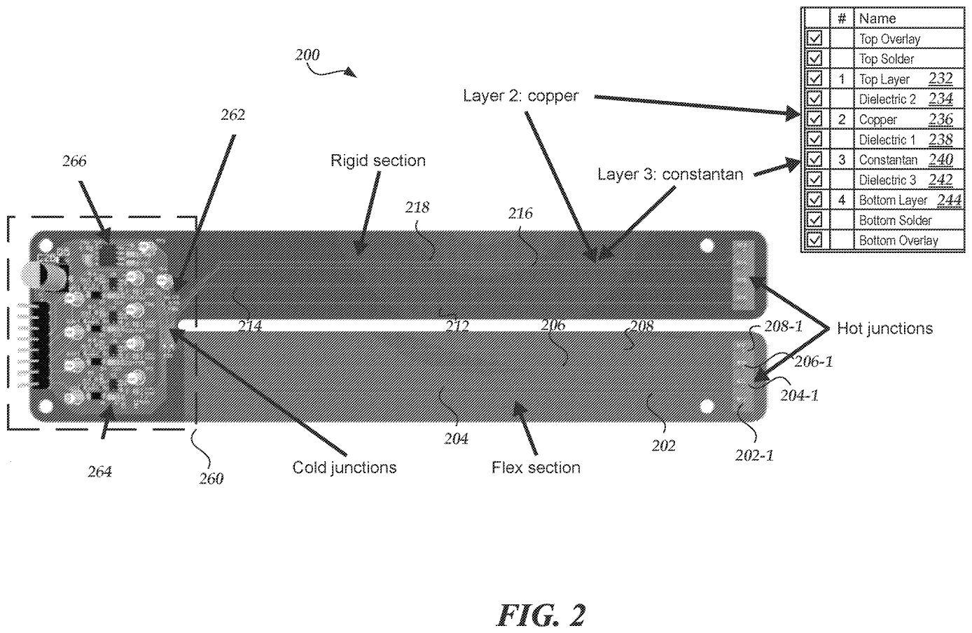

FIG. 2 shows an example PCB 200 with embedded bimetallic thermocouples in accordance with some embodiments of the present disclosure. The PCB 200 includes the bimetallic thermocouple 202, the bimetallic thermocouple 204, the bimetallic thermocouple 206, the bimetallic thermocouple 208, the bimetallic thermocouple 212, the bimetallic thermocouple 214, the bimetallic thermocouple 216, and the bimetallic thermocouple 218. As illustrated in FIG. 2, the bimetallic thermocouples 202, 204, 206, and 208 are in a flex section of the PCB 200, and the bimetallic thermocouples 212, 214, 216, and 218 are in a rigid section (made of material that is more rigid or less flexible than the flex section) of the PCB 200.

In some embodiments, each of the bimetallic thermocouples 202, 204, 206, 208, 212, 214, 216, and 218 may be a Type T (e.g., including a copper trace and a constantan trace) thermocouple. Advantageously, compared with other types of thermocouples, Type T thermocouples may be more easily printable in PCB manufacturing processes. As such, using Type T thermocouples may reduce cost and/or complexity of embedding thermocouples into a PCB.

The bimetallic thermocouples 202 may include a copper trace and a constantan trace. Constantan is a copper-nickel alloy that can be 55% copper and 45% nickel. A thermocouple with a copper trace and a constantan trace can be used to detect temperatures in a range from −200° C. to 400° C. Such a thermocouple can have an electromotive force over a temperature range of- 6.258 millivolts (mV) to 20.872 mV. In addition, such a thermocouple can have a Seebeck coefficient of 38.75 μV/° C. at 0° C. While FIG. 2 may be described with reference to Type T thermocouples, any suitable principles and advantages discussed with reference to FIG. 2 and/or any other embodiments can be applied to any suitable type of thermocouple.

As shown in FIG. 2, the copper trace and the constantan trace at one end of the bimetallic thermocouple 202 are shorted together to form a junction 202-1 (e.g., a “hot” junction). By measuring and processing a voltage difference between the other end of the bimetallic thermocouple 202, a processing circuit 260 can determine a temperature at the junction 202-1. A copper trace and a constantan trace at one end of the bimetallic thermocouples 204, 206, and 208 may also be shorted to form junctions 204-1, 206-1, and 208-1 (e.g., “hot” junctions), respectively.

In some embodiments, the processing circuit 260 may include a reference resistive thermal device (RTD) 262, an amplifier and filter module 264, and a power supply circuit 266. The reference RTD 262 may change its resistance according to temperature to provide a reference voltage for the processing circuit 260. The amplifier and filter module 264 may amply voltage signals received from each of the bimetallic thermocouples embedded in the PCB 200. The power supply circuit 266 can generate a supply voltage for the processing circuit 260. For example, the power supply circuit 266 can generate a 3 V rail for the processing circuit 260. The processing circuit 260 can include any suitable circuitry to process output signal(s) from thermocouple(s) and/or to control operation of wireless charging (e.g., ceasing wireless charging) in response to detecting an object.

As illustrated in FIG. 2, the PCB 200 has a layer 232 (e.g., a top layer), a layer 234 (e.g., a dielectric layer), a layer 236 (e.g., a copper layer), a layer 238 (e.g., a dielectric layer), a layer 240 (e.g., a constantan layer), a layer 242 (e.g., a dielectric layer), and a layer 244 (e.g., a bottom layer). Copper traces of the bimetallic thermocouples 202, 204, 206, 208, 212, 214, 216, and 218 may be in the layer 236, and constantan traces of the bimetallic thermocouples 202, 204, 206, 208, 212, 214, 216, and 218 may be in the layer 240. Traces of the bimetallic thermocouples 202, 204, 206, 208, 212, 214, 216, and 218 may be routed in any other suitable layered configurations (e.g., copper traces routed in the layer 244 and constantan traces routed in the layer 240; copper traces routed in the layer 232 and constantan traces routed in the layer 236) associated with the PCB 200 and/or other suitable PBCs. Although FIG. 2 illustrates the bimetallic thermocouples 202, 204, 206, 208, 212, 214, 216, and 218 are substantially in parallel, it should be noted that bimetallic thermocouples embedded in the PCB 200 may correspond to any other suitable patterns, including various geometrical patterns (e.g., radial patterns, or any other regular or irregular patterns).

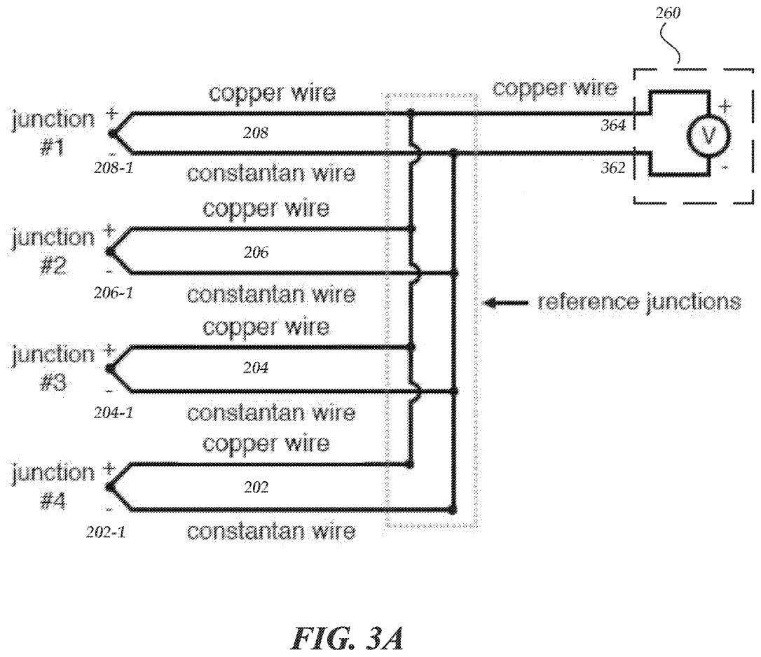

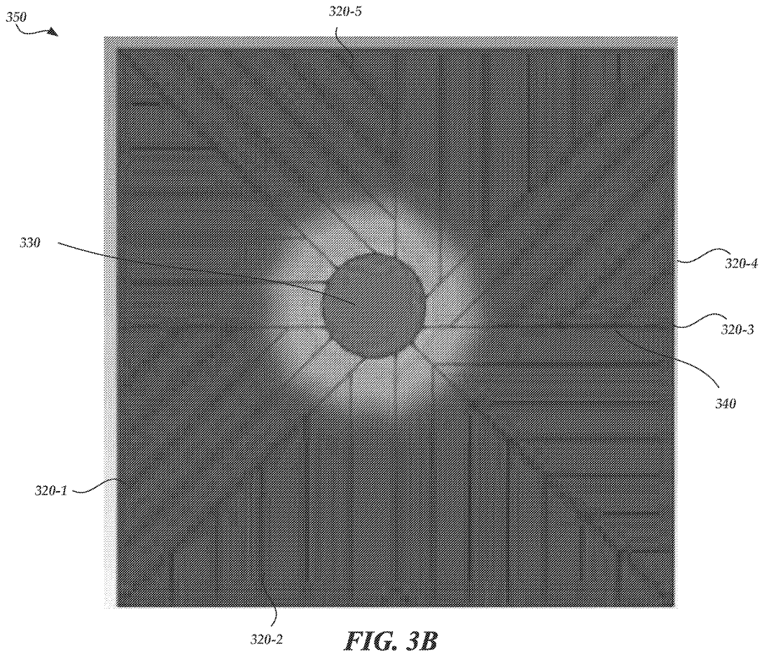

In some embodiments, for each of the bimetallic thermocouples 202, 204, 206, 208, 212, 214, 216, and 218, the processing circuit 260 may measure a voltage and determine a temperature. As such, the processing circuit 260 may make eight voltage measurements to determine eight temperature values. In some other embodiments (e.g., as illustrated in FIG. 3A), copper traces of some of the bimetallic thermocouples 202, 204, 206, 208, 212, 214, 216, and 218 may be shorted, and constantan traces of some of the bimetallic thermocouples 202, 204, 206, 208, 212, 214, 216, and 218 may be shorted to measure average temperatures using fewer measurements, more details of which will be described below with reference to FIG. 3A.

FIG. 3A illustrates example connections between bimetallic thermocouples 202, 204, 206, and 208 embedded in the PCB 200. As noted above, the copper trace and constantan trace of the bimetallic thermocouple 202 may be shorted to form the junction 202-1; the copper trace and constantan trace of the bimetallic thermocouple 204 may be shorted to form the junction 204-1; the copper trace and constantan trace of the bimetallic thermocouple 206 may be shorted to form the junction 206-1; and the copper trace and constantan trace of the bimetallic thermocouple 208 may be shorted to form the junction 208-1. Although the bimetallic thermocouples 202, 204, 206, and 208 are shown to be substantially in parallel, other geometrical arrangements or patterns (e.g., radial patterns, tree-like patterns, or the like) may be utilized.

As shown in FIG. 3A, the copper traces of the bimetallic thermocouples 202, 204, 206, and 208 are shorted and the constantan traces of the bimetallic thermocouples 202, 204, 206, and 208 are shorted. The copper traces of the bimetallic thermocouples 202, 204, 206, and 208 may be connected to an input terminal 364 of the processing circuit 260, and the constantan traces of the bimetallic thermocouples 202, 204, 206, and 208 may be connected to an input terminal 362 of the processing circuit 260. Because of shorting the copper traces and the constantan traces respectively, a voltage difference between the input terminal 362 and the input terminal 364 may be a weighted average of voltage differences between copper traces and constantan traces of the bimetallic thermocouples 202, 204, 206 and 208. The weighted average can be based on relative resistances between the bimetallic thermocouples 202, 204, 206 and 208, which may be related to lengths and/or thicknesses of traces of the bimetallic thermocouples 202, 204, 206 and 208. As such, the processing circuit 260 may measure an average temperature associated with bimetallic thermocouples 202, 204, 206 and 208 in one measurement.

For example, assume, without shorting any copper traces (or constantan traces) with each other, that a voltage difference between the copper trace and the constantan trace of the bimetallic thermocouple 202 is V1, a voltage difference between the copper trace and the constantan trace of the bimetallic thermocouple 204 is V2, a voltage difference between the copper trace and the constantan trace of the bimetallic thermocouple 206 is V3, and a voltage difference between the copper trace and the constantan trace of the bimetallic thermocouple 208 is V4. By shorting the copper traces of the bimetallic thermocouples 202, 204, 206, and 208, and the constantan traces of the bimetallic thermocouples 202, 204, 206, and 208, a voltage difference between the input terminal 362 and the input terminal 364 can be the average of V1, V2, V3, and V4 assuming equal weighting in averaging. As such, rather than measuring four voltage differences and processing four voltage differences individually to determine four temperatures, the processing circuit 260 may make one measurement and process an average voltage difference to determine an average temperature. Advantageously, through shorting first metallic traces and shorting second metallic traces of thermocouples, the processing circuit 260 may determine average temperature over a large area associated with the PCB 200 at reduced signal processing complexity and a reduced number of voltage measurements.

FIG. 3B illustrates an example routing pattern 350 of bimetallic thermocouples embedded in a PCB in accordance with some embodiments of the present disclosure. As shown in FIG. 3B, the routing pattern 350 includes bimetallic thermocouples 320-1, 320-2, 320-3, 320-4. The bimetallic thermocouples 320 include a radial pattern, where each of the bimetallic thermocouples 320-1, 320-2, 320-3, 320-4, or the like is routed to emanate outward from the central area. An object 330 generating heat can be detected over the routing pattern 350 in FIG. 3B. In some embodiments, some of the bimetallic thermocouples 320-1, 320-2, 320-3, 320-4, or the like may share one or more “hot” junctions. For example, the bimetallic thermocouples 320-4 and 320-3 share a “hot” junction 340. It should be noted that other types of connections (e.g., tree-like connections) between bimetallic thermocouples may also be employed to embed bimetallic thermocouples into a PCB according to other embodiments of the present disclosure.

Thermocouples embedded in a PCB can be used in a variety of applications. Example applications for thermocouples embedded in a PCB include, but are not limited to, integrated magnetics, under power field effect transistors and/or other integrated circuits, for temperature sensing associated with for wireless charging (e.g., embedded in a PCB on which a coil for wireless charging is positioned), or for battery temperature measurements. In battery temperature measurements, embedded thermocouples can be implemented a flex PCB for fast and accurate temperature measurement. An embedded thermocouple board can include more measurement points a relatively low cost and relatively low design effort. Parallel thermocouples in accordance with any suitable principles and advantages disclosed herein can be implemented in applications where an average measurement is desired instead of an individual measurement and/or to collective measurements over a larger area.

### Thermal Sensing for Wireless Charging

In accordance with one or more aspects of the present disclosure, temperature sensors, such as bimetallic thermocouples embedded in the PCB 200 illustrated above, one or more other types of bimetallic thermocouples (e.g., surface mounted bimetallic thermocouples), and/or one or more other suitable thermal sensors (e.g., thermistors), may be integrated into a wireless charging pad (e.g., a ground pad) of a wireless charging system for sensing temperature that can be useful for various applications. With temperature sensors, one or more objects positioned between coils of wireless charging pads can be detected. In some embodiments, the temperature sensors are configured to monitor surface temperature of the wireless charging pad. For example, a PCB embedded with bimetallic thermocouples may be deployed inside a wireless charging pad to determine surface temperature of the wireless charging pad. As noted above, a bimetallic thermocouple includes two metallic strips, or traces, that are associated with different Seebeck coefficients. When the bimetallic thermocouple is exposed to different environmental inputs (e.g., temperature changes), electrons can diffuse along the wire to create a voltage difference at ends of the metallic traces at a cold junction for indicating a sensed temperature.

In some embodiments, a wireless charging pad can include a PCB printed with multiple bimetallic thermocouples to achieve temperature monitoring over determined and/or defined surface areas of the wireless charging pad. In some embodiments, a plurality of bimetallic thermocouples with junction nodes may be deployed (e.g., under a surface of a wireless charging pad) to sense temperature over the entire surface area or particular portions of surface area of the wireless charging pad.

In some embodiments, the bimetallic thermocouples can be included in a wireless charging pad for thermally detecting one or more objects on or near a surface of the wireless charging pad to mitigate undesired heat generation that may lead to ignition. Alternatively or additionally, one or more other types of sensors (e.g., magnetic field sensing, inductance change sensing, or the like) can be included in the wireless charging pad for detecting object(s) positioned between coils during wireless charging. For example, a passively sensed mini coil matrix on top of a wireless charging pad (e.g., a ground pad) may be utilized to detect objects (e.g., metal objects or the like) by monitoring the disturbance in magnetic field caused by the metal objects during the inductive charging. As another example, actively driven coil sets on top of a ground pad may be utilized to detect objects by monitoring the coil characteristics changes (e.g., inductance change) caused by the objects during the inductive charging. In another example related to thermal object detection, a wireless charging pad may utilize thermal cameras (e.g., integrated as a part of the wireless charging pad or external to the wireless charging pad) to monitor areas of the wireless charging pad for variations in temperature or threshold temperatures for object detection and/or safety in operation.

In some embodiments, sensing signals generated by temperature sensors integrated with a wireless charging pad of a wireless charging system can be provided as temperature input data to control circuitry (e.g., a processor or any other suitable circuitry) associated with the wireless charging system. The temperature input data can be monitored to detect whether the wireless charging pad may be experiencing a thermal issue. For example, the inputs can be processed by comparing temperature thresholds, temperature variation thresholds and/or other processing rules. Based on the processed temperature input (and in some instances one or more other inputs), the control circuitry can mitigate and/or determine characterized thermal issues. Thermal issue mitigation techniques can include, but are not limited, to termination of the wireless charging process, modification of one or more operational parameters, initiation of self-test procedures, initiation of thermal management procedures (e.g., fire suppression procedures, venting procedures), alerting and/or alarming processes, notification processes, the like, or any suitable combination thereof.

### Overview of Wireless Charging

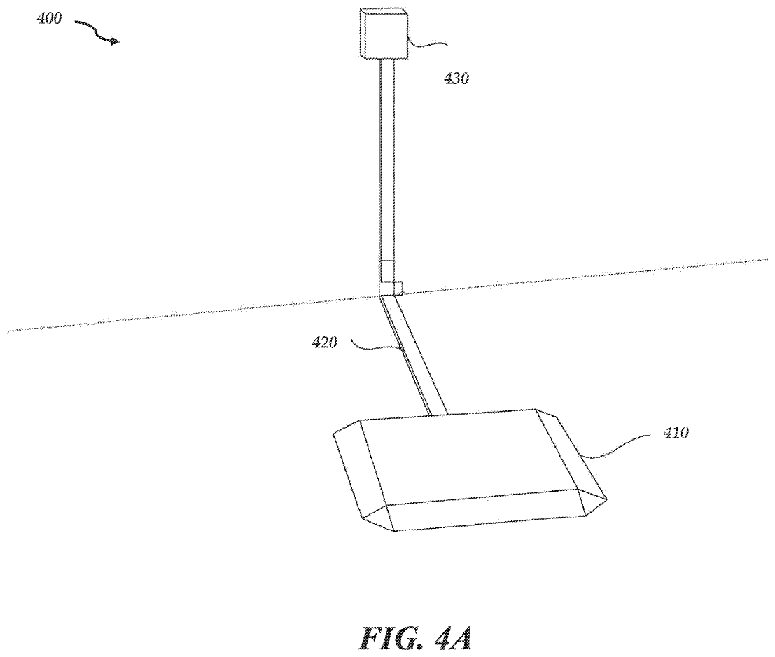

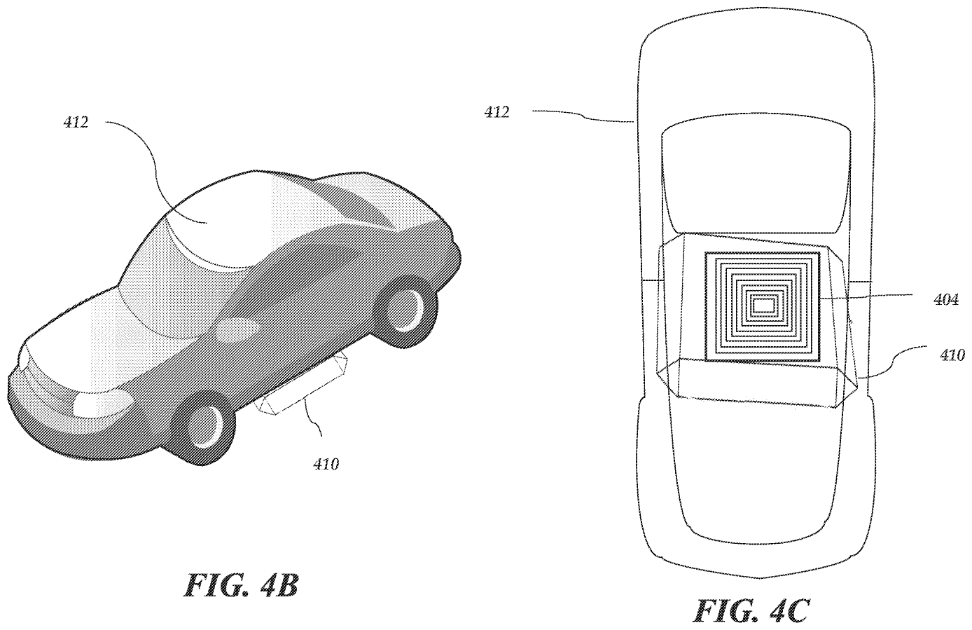

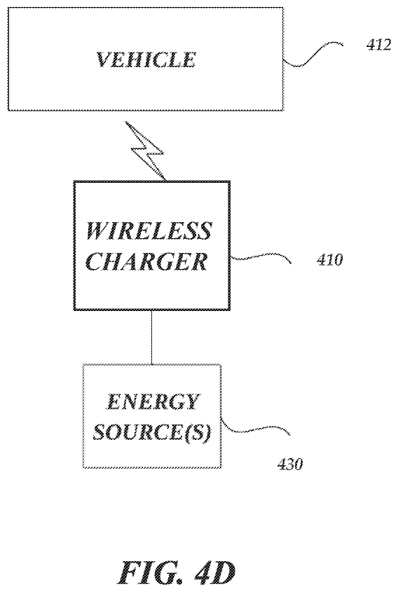

FIGS. 4A-4C are illustrations of examples of wireless charging system 400 within which temperature sensors (e.g., bimetallic thermocouples embedded in PCB, surface mounted bimetallic thermocouples, thermistors, or the like) disclosed herein can be integrated for thermally detecting objects. More specifically, according to some embodiments, a wireless charger 410 (also referred to as a “wireless charging pad” or “ground pad”) can be configured to charge a battery pack included in a vehicle. For the purpose of illustration, an electric vehicle 412 (illustrated in FIGS. 4B and 4C) coupled with a wireless charger 410 is described. However, the electric vehicle 412 is illustrated merely, for example, and the wireless charger 410 can be configured to charge any battery-powered devices, equipment, or platform that can receive the wireless energy from the wireless charger. For example, any battery-powered electric devices, robots, boats, unmanned aerial vehicles, etc., having a component (e.g., receiver coil connected to the battery pack for charging the battery pack) to receive the energy generated from the wireless charger can be coupled with the wireless charger for charging a battery pack in accordance with embodiments disclosed herein. Wireless charging disclosed herein can be applied to any suitable vehicle, including electric vehicles with a battery pack and hybrid vehicles that include an internal combustion engine and a battery pack.
FIG. 4A is a diagram of a wireless charging system 400 including a wireless charger 410, such as an induction-based wireless charger, in accordance with various aspects of the present disclosure. The wireless charging system 400 illustratively can correspond to commercial implementations, such as parking lots, parking stalls, charging booths, and the like. The wireless charging system 400 can also correspond to private or other non-commercial implementations, such as private residences, garages, etc. By way of an illustrative example, the wireless charger 410 can be configured to generate variable electromagnetic fields in accordance with some embodiments.

As also illustrated in FIG. 4A, the wireless charger 410, which can also be referred to as a transmitting component, can correspond to a stand-alone component that may be operable to be mounted or placed on a floor or other planar surfaces. In other embodiments, the wireless charger 410 can be integrated or combined with one or more other devices or components.

The wireless charger 410 may be connected to one or more energy sources (e.g., power sources), such as an input from a utility company, real-time power sources (e.g., solar cells or wind energy sources), stored energy cells, or any suitable combination thereof. The energy sources can be configured to provide the input alternating current as described herein. In some examples, the wireless charger 410 may be connected via direct electric connection 420 to the power source, such as via an energy source 430 (e.g., a junction box) located on a wall surface.

As further depicted in FIG. 4A, the wireless charger 410 can be designed with a form factor that is permissible within a designated area, which is determined by the form factor of the device intended to receive power from the wireless charger 410. For instance, if the wireless charger 410 is intended to charge a battery pack of a vehicle 412 (shown in FIG. 4B) that contains a receiver coil, then form factor of the wireless charger 410 would be such that it allows the vehicle 412 to be positioned directly over the top surface of the wireless charger 410. The dimensions of the wireless charger 410, such as its height and/or width, can be determined to ensure that the gap between the top surface of the wireless charger 410 and the receiver device's bottom surface falls within a specific range. This range can be a factor for enhancing and/or optimizing energy transfer between the wireless charger 410 and the receiver device and can be defined by minimum and maximum distances that facilitate efficient energy transfer. The appropriate distances can vary depending on the particular application. In some embodiments, the wireless charger 410 may include one or additional mechanisms for adjusting (e.g., statically adjusting and/or dynamically adjusting) this distance or altering the relative positioning between the wireless charger 410 and the receiver device to enhance and/or optimize charging efficiency.

A wireless charger 410 can provide sufficient power for charging a battery pack of an electric vehicle and also thermally detect object(s). In some embodiments, the wireless charger 410 can be configured to charge a battery pack of a vehicle, where the battery pack can have a nominal voltage of over 200 Volts (e.g., a nominal voltage of about 350 Volts or 355 Volts) and a maximum voltage of 400 Volts. In some embodiments, the wireless charger 410 can be configured to supply 800 Volts of direct current power. In some embodiments, the wireless charger 410 can supply a voltage in a range from about 200 Volts to 800 Volts.

FIGS. 4B and 4C illustrates an example of the wireless charger 410 and a vehicle 412 (e.g., electric vehicle). FIG. 4C illustrates a top view of the example the wireless charger 410 and a vehicle 412 illustrated in FIG. 4B. As illustrated in FIGS. 4B and 4C, the wireless charger 410 and the vehicle 412 can be coupled to charge a battery pack (not shown in FIGS. 4B and 4C) of the vehicle 412. For example, the wireless charger 410 and receiver coil 404 of the vehicle 412 can coupled at a threshold distance. The threshold distance can be defined as a range of distance that can provide efficient energy transfer between the wireless charger 410 and the receiver coil 404. For example, if the efficient energy transfer is defined as 85% of the energy generated from the wireless charger 410, the threshold distance can correspond to the distance that can provide at least 85% of the energy transfer between the wireless charger 410 and the receiver coil 404 of the vehicle 412.

In accordance with aspects of the present disclosure, the wireless charger 410 can be configured to transfer energy through inductive coupling with receiver coil 404, such that the receiver coil 404 can be configured to receive energy from the wireless charger 410 via inductive coupling with the wireless charger 410. Illustratively, the wireless charger 410 can include an energy transferring component, such as a transmitter coil. Such a transmitter coil can be an induction coil. The wireless charger 410 can generally be referred to as a charging station, a charging pad, or a ground pad. Such a transmitter coil can be configured to induce electromagnetic fields from power received from an energy source. The power can be provided as an alternating current provided from a power source, such as a wall outlet, an external battery, and the like. This alternating current (AC) can pass through the transmitter coil. For example, such AC current may flow into the transmitter coil, resulting in the electric charges moving through the transmitter coil. These movements in the transmitter coil can induce (or elicit) electromagnetic fields. Illustratively, the receiver coil 404 included in the vehicle 412 may receive the electromagnetic fields by locating it within a certain distance from the wireless charger 410 (e.g., the receiver coil 404 is located above the wireless charger 410 in a threshold distance). The threshold distance can be determined based on the strength of the generated electromagnetic fields and also a criterion that defines the transfer energy ratio between the wireless charger 410 and the receiver coil 404. When the receiver coil 404 receives the electromagnetic fields generated from the transmitter coil of the wireless charger 410, the strength of electromagnetic fields may fluctuate, at least in part, on changes or fluctuations in the AC amplitude. This changing of the electromagnetic field can create an alternating electric current in the receiver coil on the vehicle 412. The induced alternating current in the receiver coil 404 can then be converted into direct current to charge the battery of the vehicle 412. For example, the induced alternating current can be transmitted through a rectifier, and the rectifier may convert the induced alternating current to direct current. Then, the vehicle 412 can be configured to use the direct current to charge its battery or provide operating power, or a combination thereof.

FIG. 4D illustrates a general block diagram of the wireless charging system that includes a wireless charger 410 wirelessly coupled a vehicle 412. The wireless coupling can be via induction-based electromagnetic fields induced by a transmitter coil of the wireless charger 410. The wireless charger 410 is further connected to one or more energy sources 430, such as a power wall, external battery, external power generator (e.g., solar energy), and the like. Although the wireless charger 410 is illustrated with a direct connection to the energy sources 430, at least some portion of the input, alternating current could also be provided via a wireless transmission method. Additionally, in embodiments with multiple power sources, the environment may also include various switching components to cause the selection of energy from energy sources 430 or a combination of energy sources 430.

In some embodiments, as shown in FIG. 4D, the wireless charger 410 and the vehicle 412 are coupled via electromagnetic fields generated from a transmitter coil of the wireless charger 410. In accordance with aspects of the present disclosure, the wireless charger 410 can be configured to transfer energy through inductive coupling with receiver coil 404 of the vehicle 412, such that the receiver coil 404 is configured to receive energy from the wireless charger 410 via inductive coupling with the wireless charger 410. In some embodiments, the energy source(s) 430 can provide input AC power to the wireless charger 410. This AC power includes AC currents and passes through the transmitter coil. The electromagnetic fields can be induced by the transmitter coil due to the AC currents. The induced electromagnetic fields can radiate externally (e.g., from the wireless charger 410) to a certain direction, such as vertical direction on the wireless charger (e.g., the transmitter coil is implemented in the wireless charger facing vertically upward from the wireless charger 410). In some cases, the strengths of these vertically propagating electromagnetic field can be diminished in proportional to the distance from the top surface of the wireless charger 410. Thus, the vehicle 412 (e.g., the receiver coil 404) can be located above the wireless charger 410 within a threshold distance that can provide required strength of the electromagnetic fields.

### Example Applications in Wireless Charging

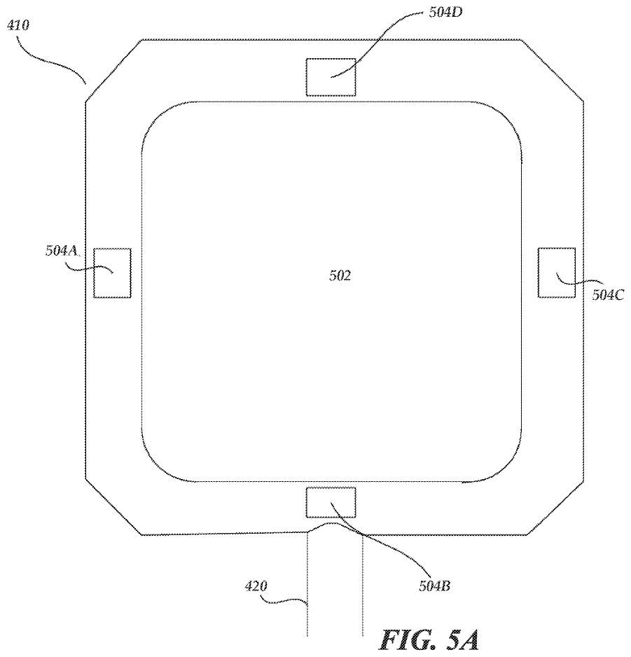

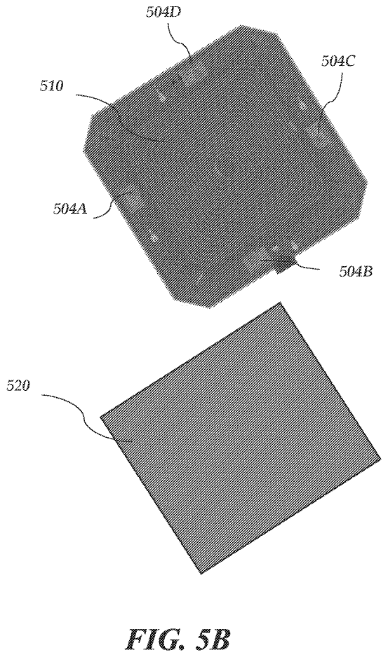

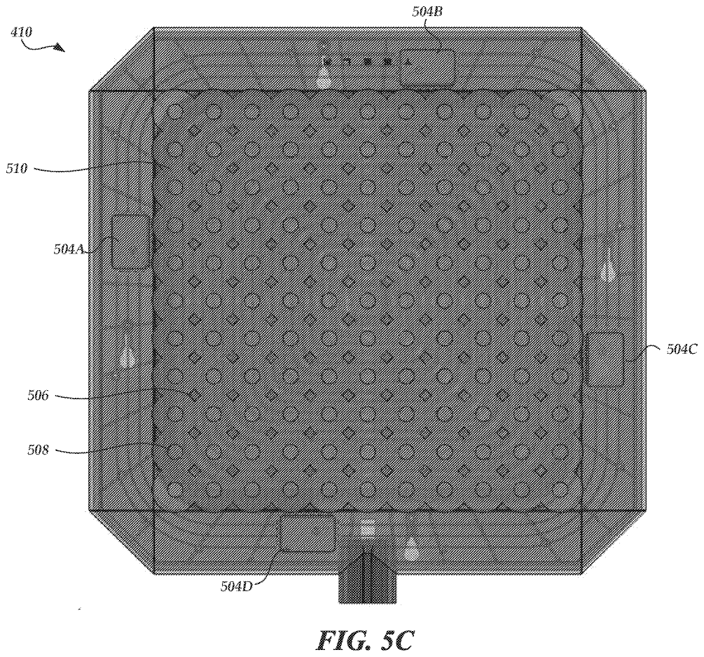

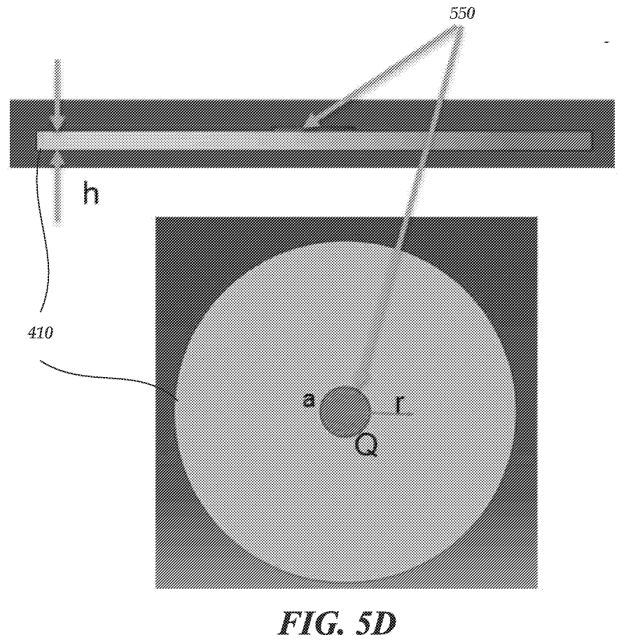

FIG. 5A illustrates a block diagram of the wireless charger 410 in which embodiments of the present disclosure can be implemented. The wireless charger 410 can include at least a coil (shown in FIGS. 5B-5C) for causing the generation of magnetic fields from an input current provided from an energy source 430. As illustrated in FIG. 5A, the input current can be provided by a direct electric connection 420.

In some embodiments, the center portion 502 of the wireless charger 410 can include temperature sensors, such as bimetallic thermocouple(s) embedded in a PCB, surface mounted bimetallic thermocouples, thermistors, the like, or any suitable combination thereof. More specifically, a plurality of bimetallic thermocouples and/or thermistors can be deployed below a surface of the center portion 502 for sensing temperature(s) associated with various locations of the center portion 502 of the wireless charger 410. For example, the plurality of bimetallic thermocouples and/or thermistors may sense temperatures to enable the wireless charger 410 to thermally detect heated object(s) above the center portion 502.

In some embodiments, the wireless charger 410 can also include various sensor components 504 (e.g., radar sensors) for various applications. By way of illustration, the sensor components 504A, 504B, 504C, 504D can be configured for various functions, such as detection of objects, detection of vehicle 412, measurement of distances to the vehicle 412, environmental sensing (e.g., using temperature sensors, moisture sensors, or the like), pressure sensing, and the like. In some embodiments, the sensor components 504 can include radar sensors. The sensor components 504 can include logic and processing components related to the charging process including object detection, temperature measurements, operational measurements, operational control, safety measurements, communication components, the like, or any suitable combination thereof.

FIG. 5B illustrates example layers of components located within the wireless charger 410 in accordance with some embodiments of the present disclosure. In some embodiments, on or below the center portion 502 of the wireless charger 410, a transmitter coil 510 can be located. In addition, the various sensor components 504 can be deployed around the transmitter coil 510 of the wireless charger 410.

As illustrated in FIG. 5B, the transmitter coil 510 can be configured to induce electromagnetic fields by receiving AC from the energy source(s) 430. The transmitter coil 510 may be capable of operating in various power ranges, such as up to about 500 kilowatts (KW). In some embodiments, the transmitter coil 510 can include a circular shape, and in some other embodiments, various shapes, such as rectangular shape, can be used.

In some embodiments, the wireless charger 410 can also include a PCB 520 (e.g., a control board for controlling operation of the wireless charger 410). The PCB 520 can be or include one or more PCBs, such as the PCB 200 that includes embedded bimetallic thermocouple(s) for sensing temperature associated with the wireless charger 410. Other temperature sensors (e.g., thermistors) can alternatively or additionally be deployed in and/or on the PCB 520. As such, the PCB 520 may utilize the bimetallic thermocouples or other temperature sensors to measure temperature associated with the wireless charger 410 for various purposes, such as detection of heated objects on the wireless charger 410.

In some embodiments, the PCB 520 can be positioned in a layer below the transmitter coil 510. Besides one or more bimetallic thermocouples, the PCB 520 can also include at least one or more processors and a power supply module thereon. For example, various electronic components, such as memory, a communication module, or the like, can be implemented in the PCB 520. These electronic components are merely provided as examples, and the PCB 520 can include more or fewer components thereon based on specific applications.

FIG. 5C illustrates example temperature sensors integrated within the wireless charger 410 that includes the transmitter coil 510 in accordance with some embodiments of the present disclosure. As shown in FIG. 5C, a plurality of temperature sensors 506 and 508 may be deployed on or below the center portion 502 of the wireless charger 410. The plurality of temperature sensors 506 and 508 can include any suitable combination of bimetallic thermocouples, thermistors, or other types of temperature sensors. In some embodiments, number of temperature sensors 506 and/or 508 may be determined based on an area of the wireless charger 410, types of temperature sensors utilized, and desired applications. A minimum size of an object to thermally detect can impact a number of temperature sensors included in the wireless charger 410. In some embodiments, to detect heated object(s) having a maximum dimension of about 50 millimeter (mm), there are above five hundred temperature sensors 506 and/or 508 integrated in the wireless charger 410. For example, there may be above five hundred bimetallic thermocouples embedded in one or more metal layers of the PCB 520, or above five hundred surface-mounted thermocouples. To detect a smaller object, more temperature sensors can be included in the wireless charger 410. On the other hand, to detect a larger object, fewer temperature sensors can be included in the wireless charger. In some other embodiments, there may be above one hundred temperature sensors, such as thermistors, in and/or on the PCB 520 for detecting heated object(s) having a length of about 50 mm.

FIG. 5D illustrates an example representation of an object 550 above the wireless charger 410 in accordance with embodiments of the present disclosure. The object 550 may be a metal object that is positioned above the wireless charger 410 during a wireless charging process. As such, the object 550 may be heated. The temperature sensors 506 and/or 508 (e.g., bimetallic thermocouples and/or other types of temperature sensors) may be utilized to detect the object 550.

In some embodiments, the number of temperature sensors 506 and/or 508 may be determined based on the size of the object 550. More specifically, the surface of the wireless charger 410 may not spread or conduct heat well due to its low thermal conductivity. As such, most of the heat generated in the wireless charging process may accumulate in the object 550. Thus, a density of the temperature sensors 506 and/or 508 may be correlated with the size of the object 550. For example, if the object 550 is a coin having a diameter of 50 mm, the number of temperature sensors 506 and/or 508 may need to be a value (e.g., 100, 200, 300, 400, 500, or the like, depending on the surface area of the wireless charger 410) such that every 50 mm of the wireless charger 410 is covered by a temperature sensing capability of a temperature sensor.

### Conclusion

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

It is to be understood that not necessarily all objects or advantages may be achieved in accordance with any particular example described herein. Thus, for example, those skilled in the art will recognize that some examples may be operated in a manner that achieves or optimizes one advantage or group of advantages as taught herein without necessarily achieving other objects or advantages as may be taught or suggested herein.

All of the processes described herein may be embodied in, and fully automated via, software code modules executed by a computing system that includes computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the example, some acts, events, or functions of any of the algorithms described herein can be performed in a different sequence, can be added, merged, or left out altogether (for example, not all described acts or events are necessary for the practice of the algorithms). Moreover, in some examples, acts or events can be performed concurrently, for example, through multi-threaded processing, interrupt processing, or multiple processors or processor cores, or on other parallel architectures, rather than sequentially. In addition, different tasks or processes can be performed by different machines and/or computing systems that can function together.

The various illustrative logical blocks and modules described in connection with the examples disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combination of the same, or the like. A processor can include electrical circuitry to process computer-executable instructions. In some examples, a processor includes an FPGA or other programmable device that performs logic operations without processing computer-executable instructions. A processor can also be implemented as a combination of computing devices, for example, a combination of a DSP and a microprocessor, a plurality of microprocessors, microprocessors in conjunction with a DSP core, or any other such configuration. Although described herein primarily with respect to digital technology, a processor may also include primarily analog components. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, routine, or algorithm described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium. An exemplary storage medium can be coupled to the processor device such that the processor device can read information from, and write information to, the storage medium. In the alternative, the storage medium can be integral to the processor device. The processor device and the storage medium can reside in an ASIC. The ASIC can reside in a user terminal. In the alternative, the processor device and the storage medium can reside as discrete components in a user terminal.

The processes described herein or illustrated in the figures of the present disclosure may begin in response to an event, such as on a predetermined or dynamically determined schedule, on demand when initiated by a user or system administrator, or in response to some other event. When such processes are initiated, a set of executable program instructions stored on one or more non-transitory computer-readable media (e.g., hard drive, flash memory, removable media, etc.) may be loaded into memory (e.g., RAM) of a server or other computing device. The executable instructions may then be executed by a hardware-based computer processor of the computing device. In some embodiments, such processes or portions thereof may be implemented on multiple computing devices and/or multiple processors, serially or in parallel.

Conditional language such as, among others, “can,” “could,” “might” or “may,” unless specifically stated otherwise, are otherwise understood within the context as used in general to convey that some examples include, while other examples do not include, some features, elements and/or steps. Thus, such conditional language is not generally intended to imply that features, elements and/or steps are in any way for examples or that examples necessarily include logic for deciding, with or without user input or prompting, whether these features, elements and/or steps are included or are to be performed in any particular example.

Disjunctive language such as the phrase “at least one of X, Y, or Z,” unless specifically stated otherwise, is otherwise understood with the context as used in general to present that an item, term, etc., may be either X, Y, or Z, or any combination thereof (for example, X, Y, and/or Z). Thus, such disjunctive language is not generally intended to, and should not, imply that some examples require at least one of X, at least one of Y, or at least one of Z to each be present.

Any process descriptions, elements or blocks in the flow diagrams described herein and/or depicted in the attached figures should be understood as potentially representing modules, segments, or portions of code which include executable instructions for implementing specific logical functions or elements in the process. Alternate examples are included within the scope of the examples described herein in which elements or functions may be deleted, executed out of order from that shown, or discussed, including substantially concurrently or in reverse order, depending on the functionality involved as would be understood by those skilled in the art.

It should be emphasized that many variations and modifications may be made to the above-described examples, the elements of which are to be understood as being among other acceptable examples. All such modifications and variations are intended to be included herein within the scope of this disclosure.

Any process descriptions, elements or blocks in the flow diagrams described herein and/or depicted in the attached figures should be understood as potentially representing modules, segments, or portions of code which include executable instructions for implementing specific logical functions or elements in the process. Alternate implementations are included within the scope of the examples described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B, and C” can include a first processor configured to carry out recitation A working in conjunction with a second processor configured to carry out recitations B and C.

1. A printed circuit board (PCB), comprising:
a thermocouple embedded in the PCB, the thermocouple comprising a first metallic trace and a second metallic trace, and
a dielectric layer positioned between the first metallic trace and the second metallic trace,
wherein the thermocouple is configured to generate a voltage indicative of temperature.

2. The PCB of claim 1, wherein the first metallic trace comprises copper, and wherein the second metallic trace comprises constantan.

3. (canceled)

4. The PCB of claim 1, further comprising a second dielectric layer and a third dielectric layer, wherein the first metallic trace and the second metallic trace are positioned between the second dielectric layer and the third dielectric layer.

5. The PCB of claim 1, further comprising a second thermocouple embedded in the PCB, the second thermocouple configured to generate a second voltage indicative of second temperature, wherein the temperature and the second temperature are associated with different locations.

6. The PCB of claim 5, wherein a first metallic trace of the second thermocouple has an end shorted to the first metallic trace of the thermocouple, and wherein a second metallic trace of the second thermocouple has an end shorted to the second metallic trace of the thermocouple.

7. The PCB of claim 5, wherein the thermocouple and the second thermocouple are arranged in parallel.

8. The PCB of claim 5, wherein the thermocouple and the second thermocouple are connected to a same hot junction.

9. The PCB of claim 1, further comprising:
a surface layer positioned over the thermocouple,
wherein the surface layer comprises a coil configured to generate an electromagnetic field for wireless charging.

10. The PCB of claim 1, further comprising 100 additional embedded thermocouples.

11. A wireless charging pad comprising the PCB of claim 1.

12. A PCB assembly comprising the PCB of claim 1 and a processing circuit, the processing circuit configured to determine the temperature based on the voltage.

13. A charging pad comprising:
a coil configured to generate an electromagnetic field for wireless charging;
one or more sensors configured to generate one or more sensing signals for thermally detect an object positioned over the coil; and
a processing circuit in communication with the one or more sensors, the processing circuit configured to control operation of the charging pad based at least on the one or more sensing signals.

14. The charging pad of claim 13, wherein the charging pad is configured to thermally detect the object while the coil wirelessly transfers power to a second coil in a vehicle pad of a vehicle.

15. The charging pad of claim 13, wherein the one or more sensors comprise thermocouples embedded in a printed circuit board.

16. The charging pad of claim 15, wherein the thermocouples are T type thermocouples.

17. The charging pad of claim 13, wherein the one or more sensors comprise surface-mounted thermocouples.

18. The charging pad of claim 13, wherein the one or more sensors comprise one hundred thermistors.

19. The charging pad of claim 13, wherein the processing circuit is configured to control operation of the charging pad based at least on the one or more sensing signals by at least:
determining, based on the one or more sensing signals, that the object is positioned over the coil; and
responsive to determining that the object is positioned over the coil, causing the coil to cease generating the electromagnetic field.

20. The charging pad of claim 13, wherein a maximum dimension of the object is less than 50 millimeters.

21. (canceled)

22. A method of thermal object detection, the method comprising:
thermally detecting, using a thermocouple embedded in a printed circuit board, an object positioned on a surface of a wireless charging pad, wherein the object has a maximum dimension of 50 millimeters or less.

23. (canceled)

24. (canceled)

25. (canceled)

26. (canceled)
